(19) United States
(12) Patent Application Publication
(10) Pub. No.: US 2026/0020206 A1
(43) Pub. Date: Jan. 15, 2026

(54) BOARD ASSEMBLY AND ELECTRONIC DEVICE INCLUDING SAME

(71) Applicant: SAMSUNG ELECTRONICS CO., LTD., Suwon-si (KR)

(72) Inventors: Jeong PARK, Suwon-si (KR); Hyunyoung ROH, Suwon-si (KR); Moonhyung KWON, Suwon-si (KR); Sunghun LIM, Suwon-si (KR)

(73) Assignee: SAMSUNG ELECTRONICS CO., LTD., Suwon-si (KR)

(21) Appl. No.: 19/265,574

(22) Filed: Jul. 10, 2025

Related U.S. Application Data
(63) Continuation of application No. PCT/KR2025/009996, filed on Jul. 9, 2025.

(30) Foreign Application Priority Data
Jul. 10, 2024 (KR) 10-2024-0091084
Sep. 6, 2024 (KR) 10-2024-0121755

(51) Int. Cl. H05K 9/00; H05K 1/02

(52) U.S. Cl. CPC H05K 9/0024; H05K 1/0203; H05K 2201/064

(57) ABSTRACT

An electronic device includes: a housing; and a board assembly inside the housing, where the board assembly includes: a printed circuit board including a first surface, and a second surface opposite to the first surface; an electronic component on the first surface; a shielding member on the first surface and surrounding the electronic component, where the shielding member includes: a shield can including an opening that is overlapping the electronic component with respect to a plane corresponding to the first surface, and a shielding sheet covering the opening; a heat dissipation material between the electronic component and the shielding sheet; and a wall inside the shielding member and extending along an edge of the electronic component, the wall at least partially surrounding the heat dissipation material.

### CROSS-REFERENCE TO RELATED APPLICATION(S)

This application is a continuation application, claiming priority under 35 U.S.C. § 365 (c), of International Application No. PCT/KR2025/009996, filed on Jul. 9, 2025, which is based on and claims the benefit of Korean Patent Application No. 10-2024-0091084, filed on Jul. 10, 2024, in the Korean Intellectual Property Office, and Korean Patent Application No. 10-2024-0121755, filed on Sep. 6, 2024, in the Korean Intellectual Property Office, the disclosures of each of which are incorporated by reference herein in its entirety.

### BACKGROUND

### 1. Field

The disclosure relates to an electronic device, and more specifically, to a board assembly including a heat dissipation material and an electronic device including the same.

### 2. Description of Related Art

The term “electronic device” may refer to a device that performs a specific function according to an installed program, such as a home appliance, an electronic scheduler, a portable multimedia player, a mobile communication terminal, a tablet PC, an image and sound device, a desktop or laptop PC, or a vehicle navigation system. For example, these electronic devices may output stored information as sound or images.

As the degree of integration of electronic devices increases and ultra-high-speed and high-capacity wireless communication become more widespread, single electronic devices, such as a mobile communication terminal, may be now equipped with various functions. For example, not only communication functions but also entertainment functions such as gaming, multimedia functions such as music and video playback, communication and security functions such as mobile banking, as well as schedule management and electronic wallet functions, are being integrated into a single electronic device. These electronic devices are being miniaturized to be conveniently carried by users.

### SUMMARY

Aspects will be set forth in part in the description which follows and, in part, will be apparent from the description, or may be learned by practice of the presented embodiments.

According to an aspect of the disclosure, an electronic device may include: a housing; and a board assembly inside the housing, where the board assembly includes: a printed circuit board including a first surface, and a second surface opposite to the first surface; an electronic component on the first surface; a shielding member on the first surface and surrounding the electronic component, where the shielding member includes: a shield can including an opening that is overlapping the electronic component with respect to a plane corresponding to the first surface, and a shielding sheet covering the opening; a heat dissipation material between the electronic component and the shielding sheet; and a wall inside the shielding member and extending along an edge of the electronic component, the wall at least partially surrounding the heat dissipation material.

The shield can may include a cover portion that is integral with the wall and is defining the opening.

The wall may include: a first portion connected to the cover portion; and a second portion extending from the first portion toward the first surface of the printed circuit board.

The second portion of the wall may be on the first surface of the printed circuit board.

The electronic component may include: a first integrated circuit on the first surface of the printed circuit board; and a second integrated circuit stacked on the first integrated circuit and operatively connected to the first integrated circuit, where the wall extends along a side of the second integrated circuit.

The wall may be spaced apart from the side of the second integrated circuit and face the side of the second integrated circuit.

The wall may extend from the shield can toward the first surface of the printed circuit board, where an end of the wall is spaced apart from the edge of the electronic component.

The wall may include: a first wall extending along a first side of the second integrated circuit; and a second wall extending along a second side of the second integrated circuit, the second side intersecting the first side, where a distance between the first wall and the first side is greater than a distance between the second wall and the second side.

One of the first wall or the second wall may be coupled to the shield can and a another of the first wall or the second wall may be bent from a portion of the shield can.

The wall may be bonded to an edge of the shield can, the edge defining the opening, and the wall being in contact with the shielding sheet.

The wall may be on an edge of the first integrated circuit.

The wall may be bonded to an edge of the first integrated circuit and be in contact with the shielding sheet.

The first integrated circuit may include, on a top surface thereof: a first area on which the second integrated circuit is provided; and a second area on which a portion of the heat dissipation material is provided, where the second area is between the second integrated circuit and the wall.

The heat dissipation material may include a material that is configured to be at least partially in a liquid phase or in a gel phase.

The wall may include a phase change material that is configured to be in a solid phase at ambient temperature, and configured to be in the liquid phase or the gel phase at a threshold temperature.

According to an aspect of the disclosure, a board assembly of an electronic device may include: a printed circuit board including a first surface, and a second surface opposite to the first surface; an electronic component on the first surface; a shielding member on the first surface and surrounding the electronic component, where the shielding member includes: a shield can including an opening that is overlapping the electronic component with respect to a plane corresponding to the first surface, and a shielding sheet covering the opening; a heat dissipation material between the electronic component and the shielding sheet; and a wall inside the shielding member and extending along an edge of the opening, the wall at least partially surrounding the heat dissipation material.

The electronic component may include: a first integrated circuit on the first surface of the printed circuit board; and a second integrated circuit stacked on the first integrated circuit and operatively connected to the first integrated circuit, where the wall extends along a side of the second integrated circuit.

The wall may include: a first wall extending along a first side of the second integrated circuit; and a second wall extending along a second side of the second integrated circuit, the second side intersecting the first side, where a distance between the first wall and the first side is greater than a distance between the second wall and the second side.

The shield can may include a cover portion that is integral with the wall and is defining the opening.

The heat dissipation material may include a material that is configured to be at least partially in a liquid phase or a gel phase.

According to an aspect of the disclosure, a board assembly of an electronic device may include: a printed circuit board including a first surface, and a second surface opposite to the first surface; an electronic component on the first surface; a shield can including an opening that is surrounding the electronic component with respect to a plane corresponding to the first surface; a shielding sheet covering the opening; a heat dissipation material between the electronic component and the shielding sheet; and a wall between the first surface of the printed circuit board and the shield can, the wall extending along an edge of the opening and at least partially surrounding the heat dissipation material.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an electronic device in a network environment according to an embodiment of the disclosure;

FIG. 2 is a front perspective view of an electronic device according to an embodiment of the disclosure;

FIG. 3 is a front exploded perspective view of the electronic device according to an embodiment of the disclosure;

FIG. 4 is a perspective view of a board assembly according to an embodiment of the disclosure;

FIG. 5 is a perspective view of the board assembly illustrating a state in which a heat dissipation material is applied before the shielding sheet is disposed, according to an embodiment of the disclosure;

FIG. 6 is a cross-sectional view of the board assembly taken along line A-A′ indicated in FIG. 4 according to an embodiment of the disclosure;

FIG. 7 is an enlarged view of a portion of the cross-sectional view of the board assembly illustrated in FIG. 6 according to an embodiment of the disclosure;

FIG. 8 is a top view of the board assembly before the heat dissipation material is disposed, according to an embodiment of the disclosure;

FIG. 9 is a cross-sectional view of the board assembly taken along line C-C′ indicated in FIG. 8 according to an embodiment of the disclosure;

FIG. 10 is a cross-sectional view of the board assembly taken along line D-D′ indicated in FIG. 8 according to an embodiment of the disclosure;

FIG. 11 is a top view of the board assembly before the heat dissipation material is disposed, according to an embodiment of the disclosure;

FIG. 12 is a cross-sectional view of the board assembly taken along line C-C′ indicated in FIG. 11 according to an embodiment of the disclosure;

FIG. 13 is a cross-sectional view of the board assembly taken along line D-D′ indicated in FIG. 11 according to an embodiment of the disclosure;

FIG. 14 is a cross-sectional view of a board assembly taken along line C-C′ indicated in FIG. 8 according to an embodiment of the disclosure;

FIG. 15 is a top view of the board assembly before the heat dissipation material is disposed, according to an embodiment of the disclosure;

FIG. 16 is a cross-sectional view of the board assembly taken along line E-E′ indicated in FIG. 15, illustrating a manufacturing process of the board assembly according to an embodiment of the disclosure;

FIG. 17 is a top view of the board assembly before the heat dissipation material is disposed, according to an embodiment of the disclosure; and

FIG. 18 is a cross-sectional view of the board assembly taken along line F-F′ indicated in FIG. 17, illustrating a manufacturing process of the board assembly according to an embodiment of the disclosure.

### DETAILED DESCRIPTION

The following description made with reference to the accompanying drawings may be provided in order to help a comprehensive understanding of various implementations of the disclosure defined by the claims and equivalents thereof. An exemplary embodiment set forth in the following description includes various particular details to help the understanding, but is considered one of various embodiments. Therefore, it will be apparent to those skilled in the art that various changes and modifications may be made to various implementations described herein without departing from the scope and technical idea of the disclosure. In addition, descriptions of well-known functions and configurations may be omitted for clarity and brevity.

The terms and words used in the following description and claims are not limited to bibliographical meanings, but may be used to clearly and consistently describe the various embodiments set forth herein. Therefore, it will be apparent to those skilled in the art that the following description of various implementations of the disclosure is provided only for the purpose of explanation, rather than for the purpose of limiting the disclosure defined as the scope of protection and equivalents thereto.

It should be appreciated that a singular form such as “a,” “an,” or “the” also includes the meaning as a plural form, unless the context clearly indicates otherwise. Therefore, for example, “a component surface” may mean one or more of component surfaces.

It will be understood that the terms “includes,” “comprises,” “has,” “having,” “including,” “comprising,” and the like when used in this specification, specify the presence of stated features, figures, steps, operations, components, members, or combinations thereof, but do not preclude the presence or addition of one or more other features, figures, steps, operations, components, members, or combinations thereof.

An expression that one component is “connected”, “coupled”, “supported”, or “in contact” with another component includes a case in which the components are directly “connected”, “coupled”, “supported”, or “in contact” with each other and a case in which the components are indirectly “connected”, “coupled”, “supported”, or “in contact” with each other through a third component. It will also be understood that when one component is referred to as being “on” or “over” another component, it may be directly on the other component or intervening components may also be present.

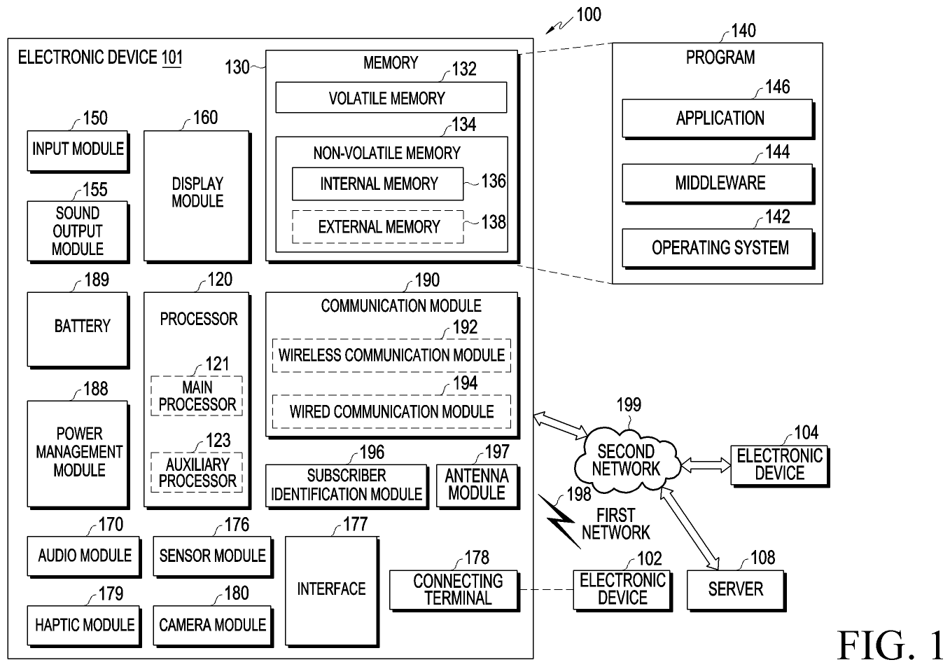

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

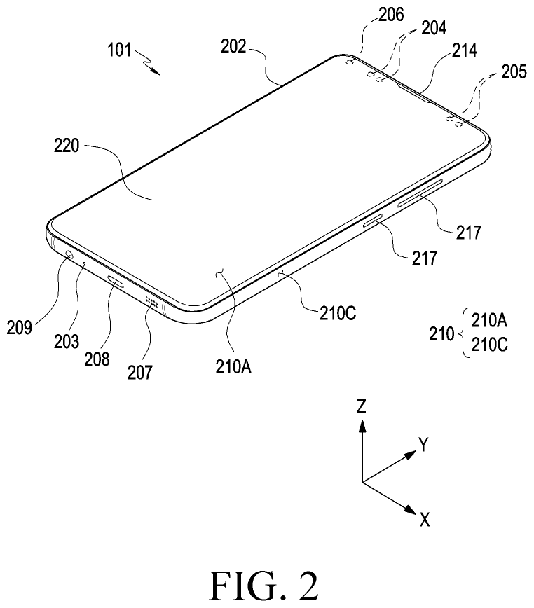

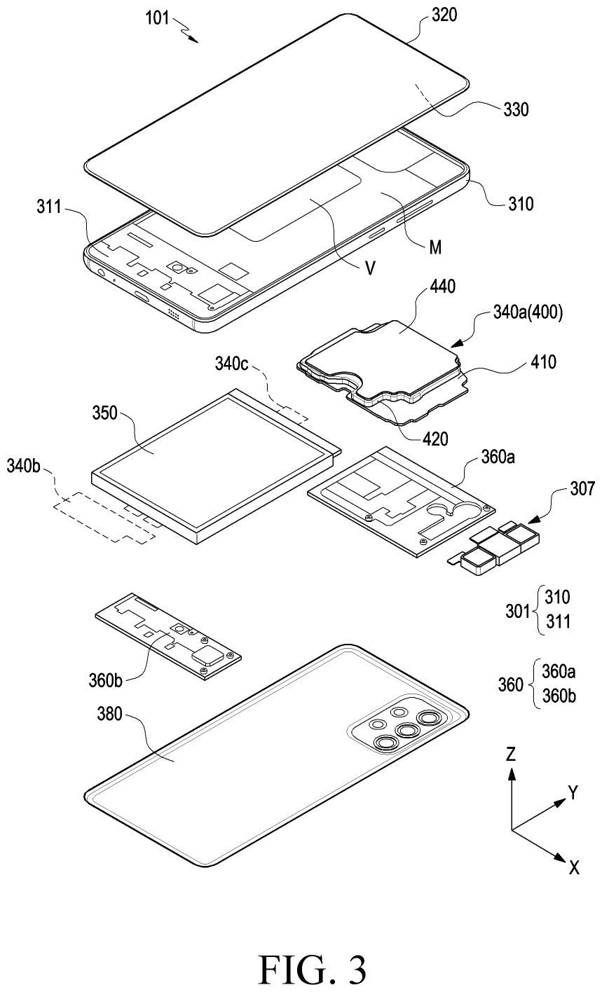

The description of the electronic device 101 given with reference to FIG. 1 may be substantially equally applied to the electronic device 101 described with reference to FIGS. 2 and 3, to the extent that they are not contradictory to each other.

FIG. 2 is a perspective view of the electronic device 101 according to an embodiment of the disclosure, illustrating the front surface 210A of the electronic device 101.

Referring to FIG. 2, the electronic device 101 (e.g., the electronic device 101 in FIG. 1) according to an embodiment of the disclosure may include a housing 210 that includes a first surface (or the front surface) 210A, a second surface (or the rear surface), and a side surface 210C surrounding the space between the first surface 210A and the second surface. According to an embodiment, at least a portion of the first surface 210A may be made of a substantially transparent front surface plate 202 (e.g., a glass plate or a polymer plate including various coating layers). The second surface may be defined by a substantially opaque rear surface plate (e.g., the rear surface plate 380 in FIG. 3).

The front surface plate 202 may include one or more areas that are curved and extend seamlessly from at least a portion of an edge toward the rear surface plate. In an embodiment, the front surface plate 202 (or the rear surface plate) may include only one of the areas bent and extending toward the rear surface plate (or the front surface plate 202), at one side edge of the first surface 210A. According to an embodiment, the front surface plate 202 or the rear surface plate may have a substantially planar shape. For example, the front or rear surface plate may not include an area that is curved and extended. When the bent and extending area is included, the thickness of the electronic device 101 in the portion including the bent and extending area may be smaller than the thicknesses of other portions.

According to an embodiment of the disclosure, the electronic device 101 may include at least one of a display 220 (e.g., the display module 160 in FIG. 1, audio modules 203, 207, and 214 (e.g., the audio module 170 in FIG. 1), a sensor module 204 (e.g., the sensor module 176 in FIG. 1), camera modules 205, 212, and 213 (e.g., the camera module 180 in FIG. 1), key input devices 217 (e.g., the input device module in FIG. 1), a light-emitting element 206, and connector holes 208 and 209 (e.g., the connection terminal 178 in FIG. 1). In an embodiment, in the electronic device 101, at least one of the components (e.g., the key input devices 217 or the light-emitting element 206) may be omitted, or other components may be additionally included.

According to an embodiment of the disclosure, the display 220 may be visually exposed through a substantial portion of, for example, the front surface plate 202. In an embodiment, at least a portion of the display 220 may be visually exposed through the front surface plate 202 forming the first surface 210A or through a portion of the side surface 210C. In an embodiment, the edge of the display 220 may be formed to be substantially the same as the shape of the periphery of the front surface plate 202 adjacent thereto. In an embodiment, the distance between the periphery of the display 220 and the periphery of the front surface plate 202 may be substantially constant in order to enlarge the visually exposed area of the display 220.

In an embodiment of the disclosure, recesses or openings may be provided in a portion of the screen display area of the display 220, and one or more of the audio module 214, the sensor modules 204, the camera modules 205, and the light-emitting elements 206, which are aligned with the recesses or the openings, may be included. In an embodiment, the rear surface of the screen display area of the display 220 may include at least one of the audio module 214, the sensor modules 204, the camera modules 205, a fingerprint sensor, and the light-emitting elements 206. In an embodiment, the display 220 may be coupled to or disposed adjacent to a touch-sensitive circuit, a pressure sensor capable of measuring a touch intensity (pressure), and/or a digitizer configured to detect an electromagnetic field-type stylus pen.

According to an embodiment of the disclosure, the audio modules 203, 207, and 214 may include a microphone hole 203 and speaker holes 207 and 214. A microphone configured to acquire external sound may be placed inside the microphone hole 203, and in an embodiment, multiple microphones may be placed to detect the direction of sound. The speaker holes 207 and 214 may include an external speaker hole 207 and a communication receiver hole 214. In an embodiment, the speaker holes 207 and 214 and the microphone hole 203 may be implemented as a single hole, or a speaker (e.g., a piezo speaker) may be included without the speaker holes 207 and 214.

According to an embodiment of the disclosure, the sensor module 204 may generate electrical signals or data values corresponding to an internal operating state or an external environmental state of the electronic device 101. The sensor module 204 may include, for example, a first sensor module 204 (e.g., a proximity sensor) and/or a second sensor module (e.g., a fingerprint sensor) disposed on the first surface 210A of the housing 210, and/or a third sensor module (e.g., a fingerprint sensor) disposed on the second surface of the housing 210. The fingerprint sensor may be disposed not only on the first surface 210A (e.g., the display 220), but also on the second surface or the side surface 210C of the housing 210. The electronic device 101 may further include at least one of, for example, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment of the disclosure, the camera modules 205, 212, and 213 may include a camera module 205 disposed on the first surface 210A of the electronic device 101 and a second camera module (e.g., the camera module 307 in FIG. 3) disposed on the second surface.

According to an embodiment of the disclosure, the key input devices 217 may be disposed on the side surface 210C of the housing 210. In an embodiment, the electronic device 101 may not include some or all of the above-mentioned key input devices 217, and the key input device 217, which are not included, may be implemented in another form, such as soft keys, on the display 220.

According to an embodiment of the disclosure, the light-emitting element 206 may be disposed on, for example, the first surface 210A of the housing 210. The light-emitting element 206 may provide, for example, the state information of the electronic device 101 in an optical form. In an embodiment, the light-emitting element 206 may provide, for example, a light source that is linked with the operation of the camera module 205. The light-emitting element 206 may include, for example, an LED, an IR LED, and a xenon lamp.

According to an embodiment of the disclosure, the connector holes 208 and 209 may include a first connector hole 208 capable of accommodating a connector (e.g., a USB connector) configured to transmit/receive power and/or data to/from an external electronic device, and/or a second connector hole 209 capable of accommodating a connector (e.g., an earphone jack) configured to transmit/receive audio signals to/from an external electronic device.

FIG. 3 is a front exploded perspective view of an electronic device 101 according to an embodiment of the disclosure. The description of the housing 210 given with reference to FIG. 2 may be substantially equally applied to the housing 301 described with reference to FIG. 3, to the extent that they are not contradictory to each other.

Referring to FIG. 3, an electronic device 101 (e.g., the electronic device 101 in FIG. 1) according to an embodiment of the disclosure may include a side surface structure 310, a first support member 311 (e.g., a bracket), a front surface plate 320, a display 330, one or more printed circuit boards (or a board assembly) 340a and 340b, a battery 350, a second support member 360 (e.g., a rear case), an antenna, a camera assembly 307, and a rear surface plate 380. When including multiple printed circuit boards 340a and 340b, the electronic device 101 may include at least one flexible printed circuit board 340c to electrically connect different printed circuit boards. For example, the printed circuit boards 340a and 340b may include a first circuit board 340a positioned above the battery 350 and a second circuit board 340b positioned below the battery 350, and a flexible printed circuit board 340c may electrically connect the first circuit board 340a and the second circuit board 340b.

According to an embodiment of the disclosure, the electronic device 101 may exclude at least one of the components (e.g., the first support member 311 or the second support member 360), or may additionally include other components. At least one of the components of the electronic device 101 may be the same as or similar to at least one of the components of the electronic device 101 of FIG. 1, and a redundant description thereof will be omitted below.

According to an embodiment of the disclosure, at least one portion of the first support member 311 may be provided in a planar shape. In an embodiment, the first support member 311 may be disposed inside the electronic device 101 to be connected to the side surface structure 310 or may be integrated with the side surface structure 310. The first support member 311 may be made of, for example, a metal material and/or a non-metal (e.g., polymer) material. When the first support member 311 is at least partially made of a metal material, a portion of the side surface structure 310 or the first support member 311 may serve as an antenna. The first support member 311 may include one surface to which the display 330 is coupled and the other surface to which the printed circuit boards 340a and 340b are coupled. An interposer, a processor, memory, and/or an interface may be mounted on the printed circuit boards 340a and 340b. The processor may include, for example, one or more of a central processing unit, an application processor, a graphics processing unit, an image signal processor, a sensor hub processor, or a communication processor.

According to an embodiment of the disclosure, the front surface plate 320 may be coupled to the support member 311 via an adhesive member. The front surface plate 320 may be referred to as a “cover” or a “front surface cover.” The front surface plate 380 may be referred to as a “cover” or a “rear surface cover.” The edge of the cover 380 may be supported by the support member 311.

According to an embodiment of the disclosure, the first support member 311 and the side surface structure 310 may be combined and referred to as a front case or a housing 301. The housing 301 may also be referred to as a frame 301. According to an embodiment, the housing 301 may be generally understood as a structure for accommodating, protecting, or arranging printed circuit boards 340a and 340b, or a battery 350.

In an embodiment of the disclosure, it may be understood that the housing 301 includes structures that a user may visually or tactfully recognize in the exterior of the electronic device 101, such as the side surface structure 310, the front surface plate 320, and/or the rear surface plate 380. The housing 301 may include a side surface structure 310, a first support member 311, a front surface plate 320, and a rear surface plate 380. In an embodiment of the disclosure, the “front or rear surface of the housing 301” may refer to the front surface plate 320 or the rear cover 380. In an embodiment, the first support member 311 may be disposed between the front surface plate 320 and the rear surface plate 380, and may function as a structure for arranging electrical/electronic components such as the printed circuit boards 340a and 340b or the camera assembly 307.

According to an embodiment of the disclosure, the memory (e.g., the memory 130 in FIG. 1) may include, for example, a volatile memory or a nonvolatile memory.

The interface may include, for example, a high-definition multimedia interface (HDMI), a universal serial bus (USB) interface, an SD card interface, and/or an audio interface. The interface may electrically or physically connect, for example, the electronic device 101 to an external electronic device, and may include a USB connector, an SD card/MMC connector, or an audio connector.

According to an embodiment of the disclosure, the second support member 360 may include, for example, an upper support member 360a and a lower support member 360b. In an embodiment, the upper support member 360a may be disposed to enclose the printed circuit board 340a or 340b (e.g., the first circuit board 340a) together with a portion of the first support member 311. For example, the upper support member 360a of the second support member 360 may be disposed to face the first support member 311 with the first circuit board 340a interposed therebetween.

In an embodiment of the disclosure, the lower support member 360b of the second support member 360 may be disposed to face the first support member 311 with the second circuit board 340b interposed therebetween. Circuit devices implemented in the form of integrated circuit chips (e.g., a processor, a communication module, or memory) or various electrical/electronic components may be disposed on a printed circuit boards 340a and 340b. According to an embodiment, the printed circuit boards 340a and 340b may be provided with an electromagnetic shielding environment from the second support member 360. In an embodiment, the lower support member 360b may be used as a structure on which electric/electronic components such as a speaker module and an interface (e.g., a USB connector, an SD card/MMC connector, or an audio connector) may be disposed.

In an embodiment of the disclosure, electrical/electronic components, such as a speaker module and an interface (e.g., a USB connector, an SD card/MMC connector, or an audio connector), may be disposed on an additional printed circuit board. For example, the lower support member 360b may be disposed to enclose the additional printed circuit board together with the other portion of the first support member 311.

The battery 350 is a device to supply power to at least one component of the electronic device 101, and may include, for example, a non-rechargeable primary battery, a rechargeable secondary battery, or a fuel cell. At least a portion of the battery 350 may be disposed on substantially the same plane as, for example, the printed circuit boards 340a and 340b. The battery 350 may be integrally disposed inside the electronic device 101 or may be detachably disposed on the electronic device 101.

The antenna may include a conductor pattern implemented on the surface of the second support member 360 through, for example, a laser direct structuring method. In an embodiment, the antenna may include a printed circuit pattern provided on the surface of a thin film, and the thin film-type antenna may be disposed between the rear surface plate 380 and the battery 350. The antenna may include, for example, a near-field communication (NFC) antenna, a wireless charging antenna, and/or a magnetic secure transmission (MST) antenna. The antenna may, for example, perform short-distance communication with an external device, or wirelessly transmit and receive power required for charging. In an embodiment, an antenna structure may be configured with a portion or a combination of the side surface structure 310 and/or the first support member 311.

According to an embodiment of the disclosure, the electronic device 101 may include a metal cover M. As an example, the housing 301 may include a metal cover M that covers a shielding sheet 440. An embodiment of the disclosure may include a vapor chamber V. The vapor chamber V may be disposed on the metal cover M. Heat generated from the board assembly 400 may be dispersed to the outside of the board assembly 400 through the metal cover M and the vapor chamber V.

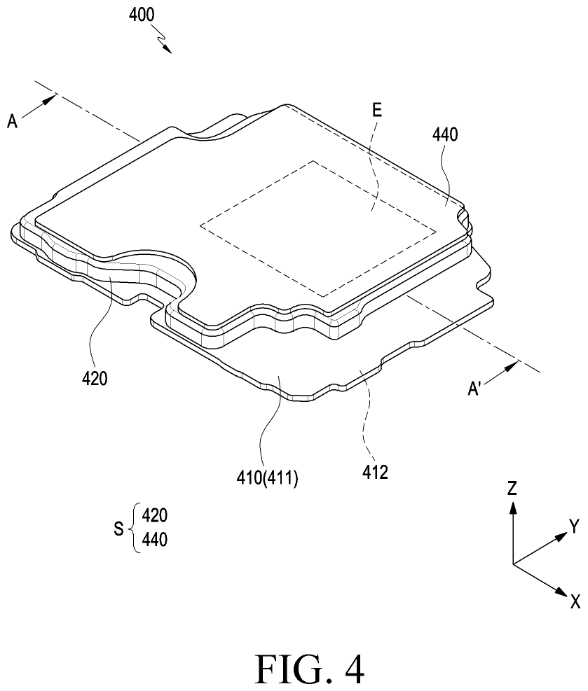

Referring to FIG. 3, the electronic device 101 according to an embodiment of the disclosure may include the board assembly 400. The board assembly 400 may include a printed circuit board and multiple electronic components (e.g., a processor, memory, and an interposer) mounted on the printed circuit board. The description of the board assembly 340a given with reference to FIG. 3 may be equally applied to the board assembly 400. The board assembly 400 may include a printed circuit board 410, a shield can 420, and/or a shielding sheet 440. The board assembly 400 will be described in detail with reference to FIGS. 4 to 18.

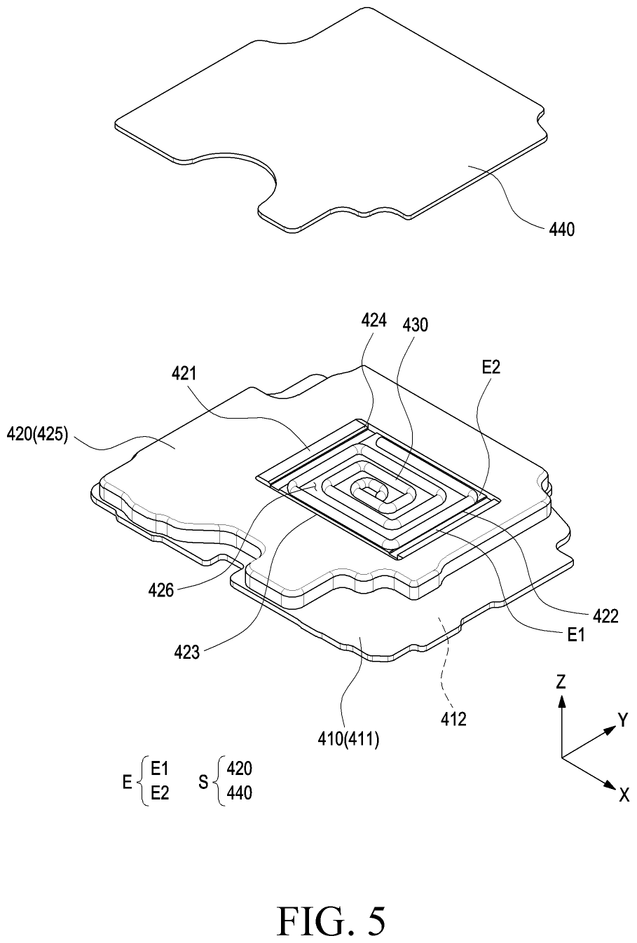

FIG. 4 is a perspective view of the board assembly 400 according to an embodiment of the disclosure. FIG. 5 is a perspective view of the board assembly 400 illustrating a state in which a heat dissipation material 430 is applied before the shielding sheet 440 is disposed, according to an embodiment of the disclosure.

Referring to FIGS. 4 and 5, the board assembly 400 according to an embodiment of the disclosure may include a printed circuit board 410 having a first surface 411 and a second surface 412 opposite to the first surface 411. As an example, the first surface 411 and the second surface 412 of the printed circuit board 410 may be understood as surfaces visually exposed to the outside.

According to an embodiment of the disclosure, the board assembly 400 may include an electronic component E disposed on the printed circuit board 410. The electronic component E may be disposed on the first surface 411 of the printed circuit board 410. As an example, the electronic component E may be mounted on the first surface 411 of the printed circuit board 410 through soldering. The electronic component E may be understood as a single integrated circuit or an assembly in which multiple (e.g., two) integrated circuits are interconnected. During the operation of the electronic component E, heat may be generated, and the generated heat may be transferred to the outside of the board assembly 400 through a heat dissipation structure (e.g., the heat dissipation material 430).

According to an embodiment of the disclosure, the board assembly 400 may include a shielding member S surrounding the electronic component E. The shielding member S may be disposed on the first surface 411. The shielding member S may block a magnetic field generated from the electronic component E from leaking to the outside of the board assembly 400 or may block an external magnetic field outside the board assembly 400 from entering the electronic component E.

According to an embodiment of the disclosure, the shielding member S may include a shield can 420 having an opening 426. When viewed from above the first surface 411 of the printed circuit board 410, the opening 426 may overlap the electronic component E. As an example, the opening 426 may have a shape corresponding to the contour of the electronic component E (e.g., a rectangle) at a position overlapping the electronic component E.

According to an embodiment of the disclosure, the shield can 420 may include a cover portion 425 facing the first surface 411 of the printed circuit board 410. As an example, the cover portion 425 may be understood as a part of the shield can 420, including the top surface of the shield can 420. The cover portion 425 may cover the electronic component E. The cover portion 425 may define the opening 426.

According to an embodiment of the disclosure, the shielding member S may include a shielding sheet 440 covering the opening 426. The edge of the shielding sheet 440 may be supported by the shield can 420 (e.g., the cover portion 425). As an example, the shielding sheet 440 may be bonded to the cover portion 425 of the shield can 420 via a conductive adhesive member.

According to an embodiment of the disclosure, the shielding sheet 440 may cover the electronic component E. Together with the shield can 420, the shielding sheet 440 may enclose the electronic component E. The shielding sheet 440 may perform an electromagnetic shielding function and may provide heat transfer paths H1 and H2 for transferring heat generated from the electronic component E to the metal cover M (see FIG. 7). As an example, the shielding sheet 440 may be a thin copper film.

According to an embodiment of the disclosure, the board assembly 400 may include a heat dissipation material 430 disposed between the electronic component E and the shielding sheet 440. The heat dissipation material 430 may be at least partially in a liquid phase or a gel phase. As an example, the heat dissipation material 430 may be in a liquid phase or a gel phase at room temperature (e.g., 25° C.). According to an embodiment of the disclosure, the gel phase of the heat dissipation material 430 may be understood as a highly flowable state in which its shape is not maintained. As an example, the gel phase may be understood as a state with flowability sufficient for injection through an injector such as a nozzle.

According to an embodiment of the disclosure, the heat dissipation material 430 may be disposed on the electronic component E. The heat dissipation material 430 may be disposed on the electronic component E through the opening 426. As an example, the board assembly 400 may be manufactured by a method in which the heat dissipation material 430 is applied to the electronic component E and then the shielding sheet 440 is pressed over the heat dissipation material. The flowable heat dissipation material 430 may spread into the inner space of the shielding member S by the shielding sheet 440.

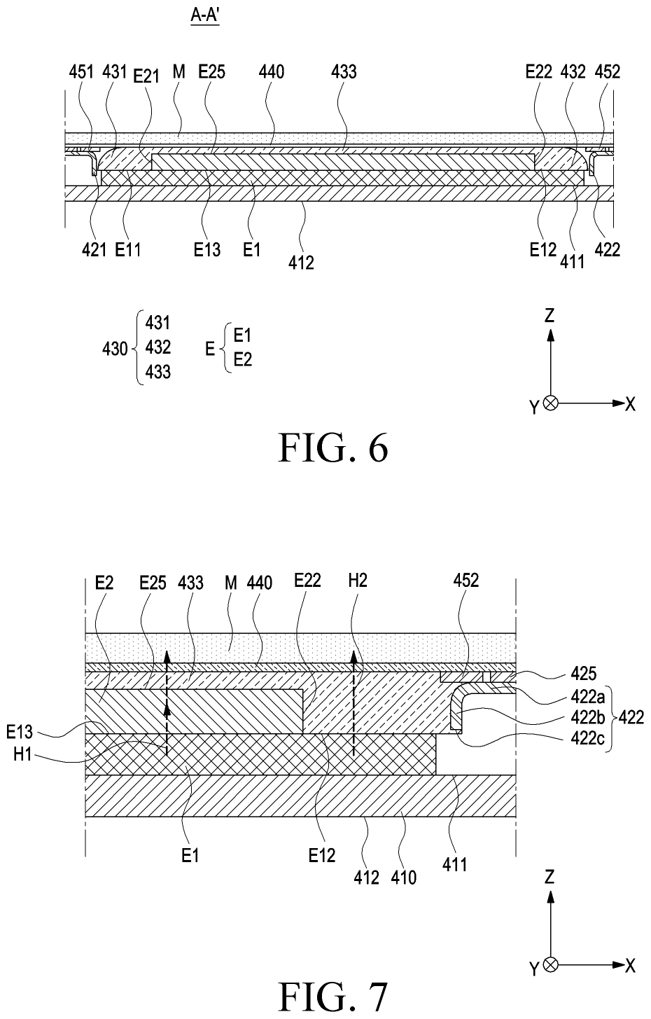

According to an embodiment of the disclosure, the board assembly 400 may include wall structure comprising a plurality of walls 421, 422, 423, and 424 positioned inside the shielding member S. The walls 421, 422, 423, and 424 may extend along the edges of the electronic component E to at least partially surround the heat dissipation material 430. The multiple members 421, 422, 423, and 424 may include a first wall 421, a second wall 422, a third wall 423, and/or a fourth wall 424. The walls 421, 422, 423, and 424 may be connected to the cover portion 425 of the shield can 420. According to an embodiment, the walls 421, 422, 423, and 424 may be integrally formed the cover portion 425 of the shield can 420, but the disclosure is not limited thereto. The walls 421, 422, 423, and 424 will be described in detail with reference to FIGS. 6 to 18.

FIG. 6 is a cross-sectional view of the board assembly 400 taken along line A-A′ indicated in FIG. 4. FIG. 7 is an enlarged view of a portion of the cross-sectional view of the board assembly 400 illustrated in FIG. 6.

Referring to FIGS. 6 and 7, according to an embodiment of the disclosure, the electronic component E may include a first integrated circuit E1 disposed on the first surface 411 of the printed circuit board 410. The electronic component E may include a second integrated circuit E2 disposed above the first integrated circuit E1. The second integrated circuit E2 may be stacked on the first integrated circuit E1. As an example, the printed circuit board 410, the first integrated circuit E1, and the second integrated circuit E2 may be sequentially stacked.

According to an embodiment of the disclosure, the second integrated circuit E2 may be electrically connected to the first integrated circuit E1. The second integrated circuit E2 may be operatively connected to the first integrated circuit E1. As an example, the first integrated circuit E1 may be a processor (e.g., the processor 120 in FIG. 1) including at least one processing core, and the second integrated circuit E2 may be memory (e.g., the memory 130 or the volatile memory 132 in FIG. 1) mounted on the first integrated circuit E1 through solder balls and storing instructions executed by the at least one processing core.

According to an embodiment of the disclosure, the second integrated circuit E2 may be disposed in an area E13 (hereinafter, referred to as a “first area”) of a top surface E11, E12, and E13 of the first integrated circuit E1. As an example, the first area E13 of the top surface E11, E12, and E13 of the first integrated circuit E1 may include a center area of the top surface E11, E12, and E13. The top surface E11, E12, and E13 of the first integrated circuit E1 may include a second area E11 and E12, in which portions 431 and 432 of the heat dissipation material 430 are disposed.

According to an embodiment of the disclosure, the heat dissipation material 430 may include first portions 431 and 432 positioned between the first integrated circuit E1 and the shielding sheet 440. The heat dissipation material 430 may include a second portion 433 positioned between the second integrated circuit E2 (more specifically, a top surface E25 of the second integrated circuit E2) and the shielding sheet 440. Heat generated from the electronic component E may be dispersed to the outside of the electronic component E through heat transfer paths H1 and H2. The first portions 431 and 432 of the heat dissipation material 430 may provide a first heat transfer path H2. The second portion 433 of the heat dissipation material 430 may provide a second heat transfer path H1. As an example, heat generated from the first integrated circuit E1 may be dispersed to the outside through the first heat transfer path H2 and the second heat transfer path H1. As an example, heat generated from the second integrated circuit E2 may be dispersed through the second heat transfer path H1.

According to an embodiment of the disclosure, the walls 421, 422, 423, and 424 may include a first wall 421 and a second wall 422. The description of the second wall 422 of the walls 421, 422, 423, and 424, given with reference to FIG. 7, may be substantially equally applied to the first wall 421 to the extent that they are not contradictory to each other. As an example, the first wall 421 and the second wall 422 may be understood as having a structure symmetrical to each other with respect to the second integrated circuit E2.

Referring to FIG. 7, according to an embodiment of the disclosure, the second wall 422 of the walls 421, 422, 423, and 424 may include a first portion 422a connected to the cover portion 425. The first portion 422a may be connected to an edge of the cover portion 425 of the shield can 420. As an example, the first portion 422a may be joined to the edge of the cover portion 425 through welding and integrated with the cover portion 425. The first portion 422a may protrude from the edge of the cover portion 425 of the shield can 420 toward the opening 426.

According to an embodiment of the disclosure, the board assembly 400 may include dam members 451 and 452. The dam members 451 and 452 may be disposed between the walls 421, 422, 423, and 424 and the shielding sheet 440. As an example, FIG. 6 illustrates a first dam member 451 and a second dam member 452, and FIG. 7 illustrates a state in which the second dam member 452 is disposed between the second wall 422 of the walls 421, 422, 423, and 424 and the shielding sheet 440.

According to an embodiment of the disclosure, the dam members 451 and 452 may prevent the heat dissipation material 430 from leaking out between the shielding sheet 440 and the cover portion 425 of the shield can 420. As an example, the dam members 451 and 452 may be made of rubber or sponge. In another example, the dam members 451 and 452 may be a heat dissipation member that is in a solid phase at room temperature (e.g., 25° C.) and includes heat dissipation particles and a paraffin-based phase change material that changes from the solid phase to a liquid phase or a gel phase at a threshold temperature (e.g., 45° C. to 65° C.). The phase change material may be a thermally responsive material that reacts to a temperature change. As an example, the phase change material may be a thermoplastic polymer. The heat dissipation particles may be carbon fiber, graphene, boron nitride (BN), silicon carbide (SiC), magnesium oxide (MgO), or zinc oxide (ZnO).

According to an embodiment of the disclosure, the second wall 422 of the walls 421, 422, 423, and 424 may include a second portion 422b bent from the first portion 422a toward the first surface 411 of the printed circuit board 410. As an example, the second portion 422b may be bent perpendicularly to the first portion 422a. The end 422c of the second portion 422b of the second wall 422 of the walls 421, 422, 423, and 424 may be spaced apart from the first surface 411 of the printed circuit board 410.

According to an embodiment of the disclosure, the second portion 422b of the second wall 422 may extend along a second side E22 of the second integrated circuit E2. The second portion 422b may be spaced apart from the second side E22 of the second integrated circuit E2. As an example, the second portion 422b may be positioned outward of an edge of the second integrated circuit E2.

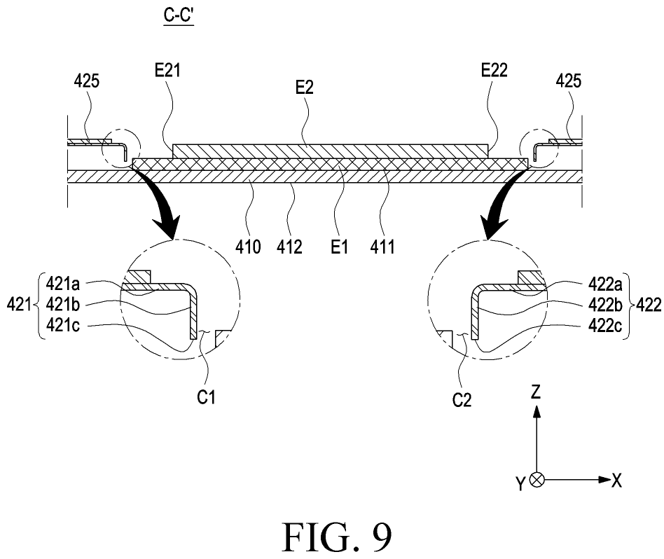

According to an embodiment of the disclosure, the second portion 422b of the second wall 422 may face the second side E22 of the second integrated circuit E2. The second portion 421b of the first wall 421 (see FIG. 9) may face the first side E21 of the second integrated circuit E2. The second portion 422a of the first wall 421 may extend along the first side E21 of the second integrated circuit E2.

According to an embodiment of the disclosure, since the heat dissipation material 430 is confined within the space defined by the walls 421, 422, 423, and 424 (e.g., the second wall 422), the coating area and the coating amount of the heat dissipation material 430 may be increased, which may lead to the improvement of the heat dissipation performance of the electronic component E. If the walls 421, 422, 423, and 424 are absent, the heat dissipation material 430 may be partially applied to the central area of the electronic component E (e.g., the top surface E25 of the second integrated circuit E2) to prevent the heat dissipation material 430 from flowing out from the surfaces of the first integrated circuit E1 and the second integrated circuit E2. As a result, compared to an embodiment of the disclosure, the heat dissipation performance may be reduced. When a non-flowable (e.g., solid-phase) heat dissipation member is used instead of the heat dissipation material 430, which serves as a heat dissipation member for the electronic component E, unlike an embodiment of the disclosure, deformation may occur in surrounding structures (e.g., the metal cover M or the display 330 in FIG. 3) when the assembly of the board assembly 400 and/or the electronic device 101 is completed.

According to an embodiment of the disclosure, the board assembly 400 may secure the contact area with the electronic component E by substantially fixing the position of the liquid-phase or gel-phase heat dissipation material 430 by the walls 421, 422, 423, and 424. In addition, by calculating the area of the space defined by the walls 421, 422, 423, and 424, the application amount of the heat dissipation material 430 may be precisely determined, thereby enabling optimization of material cost relative to heat dissipation performance.

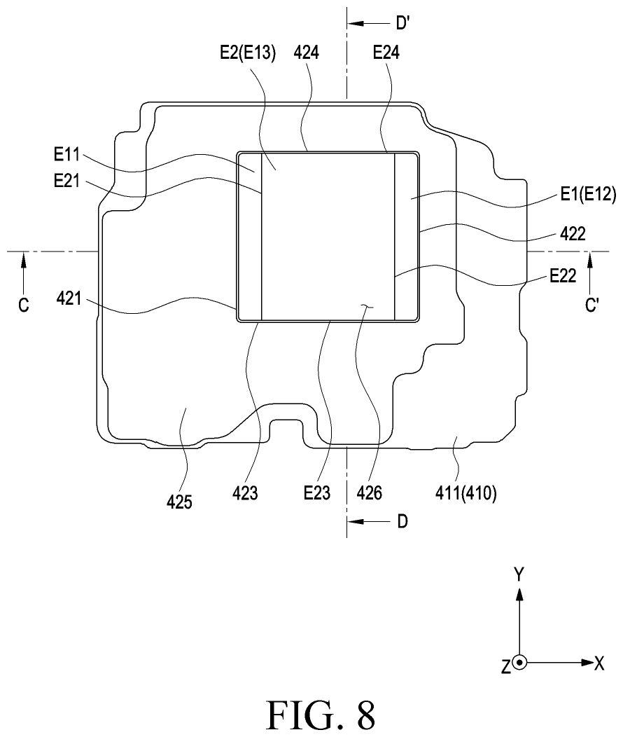

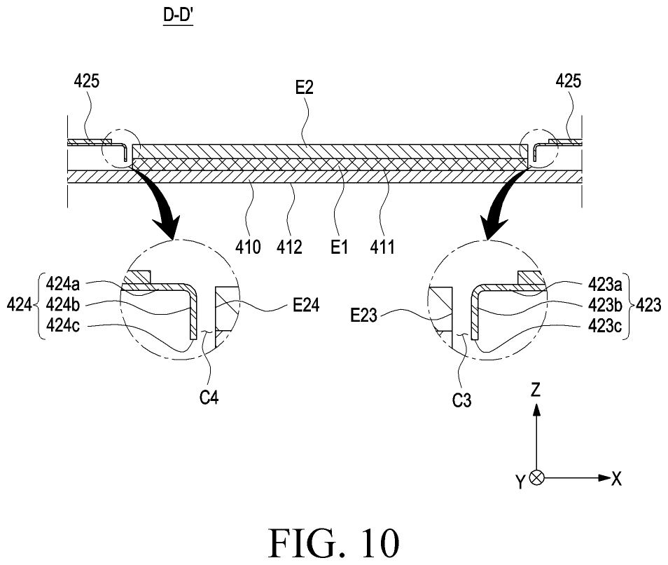

FIG. 8 is a top view of a portion of the board assembly 400 before the heat dissipation material 430 is disposed, according to an embodiment of the disclosure. FIG. 9 is a cross-sectional view of the board assembly 400 taken along line C-C′ indicated in FIG. 8. FIG. 10 is a cross-sectional view of the board assembly 400 taken along line D-D′ indicated in FIG. 8.

Referring to FIG. 8, the second integrated circuit E2 according to an embodiment of the disclosure may include multiple sides E21, E22, E23, and E24. Among the multiple sides E21, E22, E23, and E24, two adjacent sides may intersect each other, and as an example, may be orthogonal to each other. For convenience of explanation, the multiple sides E21, E22, E23, and E24 may be referred to as a first side E21, a second side E22, a third side E23, and a fourth side E24.

According to an embodiment of the disclosure, the first wall 421 of the walls 421, 422, 423, and 424 may extend along the first side E21 of the second integrated circuit E2. The first wall 421 may be spaced apart from the first side E21 of the second integrated circuit E2. The first wall 421 may face the first side E21 of the second integrated circuit E2.

According to an embodiment of the disclosure, the second wall 422 of the walls 421, 422, 423, and 424 may extend along the second side E22 of the second integrated circuit E2. The second wall 422 may be spaced apart from the second side E22 of the second integrated circuit E2. The second wall 422 may face the second side E22 of the second integrated circuit E2.

According to an embodiment of the disclosure, the third wall 423 of the walls 421, 422, 423, and 424 may extend along the third side E23 of the second integrated circuit E2. The third wall 423 may be spaced apart from the third side E23 of the second integrated circuit E2. The third wall 423 may face the third side E23 of the second integrated circuit E2.

According to an embodiment of the disclosure, the fourth wall 424 of the walls 421, 422, 423, and 424 may extend along the fourth side E24 of the second integrated circuit E2. The fourth wall 424 may be spaced apart from the fourth side E24 of the second integrated circuit E2. The fourth wall 424 may face the fourth side E24 of the second integrated circuit E2.

Referring to FIGS. 8 and 9, according to an embodiment of the disclosure, the first wall 421 of the walls 421, 422, 423, and 424 may include a second portion 421b bent from the first portion 421a toward the first surface 411 of the printed circuit board 410. As an example, the second portion 421b may be bent perpendicularly to the first portion 421a. The end 421c of the second portion 421b of the first wall 421 of the walls 421, 422, 423, and 424 may be spaced apart from the first surface 411 of the printed circuit board 410.

According to an embodiment of the disclosure, the second portion 421b of the first wall 421 may extend along the second side E22 of the second integrated circuit E2. The second portion 421b may be spaced apart from the second side E22 of the second integrated circuit E2. As an example, the second portion 421b may be positioned outward of an edge of the first integrated circuit E1.

According to an embodiment of the disclosure, the second portion 421b of the first wall 421 may face the first side E21 of the second integrated circuit E2. The second portion 421b of the first wall 421 (see FIG. 9) may face the first side E21 of the second integrated circuit E2. The second portion 421b of the first wall 421 may extend along the first side E21 of the second integrated circuit E2.

According to an embodiment of the disclosure, the end 421c of the first wall 421 of the walls 421, 422, 423, and 424 may be spaced apart from an edge of the electronic component E. As an example, the end 421c of the first wall 421 may be spaced outward from the edge of the first integrated circuit E1. A first gap C1 may be formed between the end 421c of the first wall 421 and the edge of the first integrated circuit E1.

According to an embodiment of the disclosure, the end 422c of the second wall 422 of the walls 421, 422, 423, and 424 may be spaced apart from the edge of the electronic component E. As an example, the end 422c of the second wall 422 may be spaced outward from the edge of the first integrated circuit E1. A second gap C2 may be formed between the end 422c of the second wall 422 and the edge of the first integrated circuit E1.

Referring to FIGS. 8 and 10, according to an embodiment of the disclosure, the walls 421, 422, 423, and 424 may include a third wall 423, which is integrated with the cover portion 425 of the shield can 420. The third wall 423 may be connected to the edge of the cover portion 425 of the shield can 420. As an example, the third wall 423 may be formed by bending a portion of the edge of the shield can 420. The third wall 423 may include a first portion 423a connected to the cover portion 425. The first portion 423a of the third wall 423 may be connected to the edge of the cover portion 425.

According to an embodiment of the disclosure, the third wall 423 of the walls 421, 422, 423, and 424 may include a second portion 423b bent from the first portion 423a toward the first surface 411 of the printed circuit board 410. As an example, the second portion 423b may be bent perpendicularly to the first portion 423a. The end 423c of the second portion 423b may be spaced apart from the first surface 411 of the printed circuit board 410.

According to an embodiment of the disclosure, the second portion 423b of the third wall 423 may extend along the third side E23 of the second integrated circuit E2. The second portion 423b of the third wall 423 may be spaced apart from the third side E23 of the second integrated circuit E2. As an example, the second portion 423b may be positioned outward of the edge of the second integrated circuit E2.

According to an embodiment of the disclosure, the second portion 423b of the third wall 423 may face the third side E23 of the second integrated circuit E2. The second portion 423b (see FIG. 9) of the third wall 423 may face the third side E23 of the second integrated circuit E2. The second portion 423b of the third wall 423 may extend along the third side E23 of the second integrated circuit E2.

According to an embodiment of the disclosure, the end 423c of the third wall 423 of the walls 421, 422, 423, and 424 may be spaced apart from the edge of the electronic component E. As an example, the end 423c of the third wall 423 may be spaced outward from the edge of the first integrated circuit E1. A third gap C3 may be formed between the end 423c of the third wall 423 and the edge of the first integrated circuit E1.

According to an embodiment of the disclosure, the walls 421, 422, 423, and 424 may include a fourth wall 424, which is integrated with the cover portion 425 of the shield can 420. The fourth wall 424 may be connected to the edge of the cover portion 425 of the shield can 420. As an example, the fourth wall 424 may be formed by bending a portion of the edge of the shield can 420. The fourth wall 424 may include a first portion 424a connected to the cover portion 425. The first portion 424a of the fourth wall 424 may be connected to the edge of the cover portion 425.

According to an embodiment of the disclosure, the fourth wall 424 of the walls 421, 422, 423, and 424 may include a second portion 424b bent from the first portion 424a toward the first surface 411 of the printed circuit board 410. As an example, the second portion 424b may be bent perpendicularly to the first portion 424a. The end 424c of the second portion 424b may be spaced apart from the first surface 411 of the printed circuit board 410.

According to an embodiment of the disclosure, the second portion 424b of the fourth wall 424 may extend along the fourth side E24 of the second integrated circuit E2. The second portion 424b of the fourth wall 424 may be spaced apart from the fourth side E24 of the second integrated circuit E2. As an example, the second portion 424b may be positioned outward of the edge of the second integrated circuit E2.

According to an embodiment of the disclosure, the second portion 424b of the fourth wall 424 may face the fourth side E24 of the second integrated circuit E2. The second portion 424b (see FIG. 9) of the fourth wall 424 may face the fourth side E24 of the second integrated circuit E2. The second portion 424b of the fourth wall 424 may extend along the fourth side E24 of the second integrated circuit E2.

According to an embodiment of the disclosure, the end 424c of the fourth wall 424 of the walls 421, 422, 423, and 424 may be spaced apart from the edge of the electronic component E. As an example, the end 424c of the fourth wall 424 may be spaced outward from the edge of the first integrated circuit E1. A fourth gap C4 may be formed between the end 424c of the third wall 424 and the edge of the first integrated circuit E1.

Referring to FIG. 5, according to an embodiment of the disclosure, the board assembly 400 may be manufactured by applying the heat dissipation material 430 onto the electronic component E and then placing the shielding sheet 440 on the shield can 420 so as to cover the opening 426. The heat dissipation material 430 may flow within the space surrounded by the walls 421, 422, 423, and 424 due to the placed shielding sheet 440. At this time, the air present in the space surrounded by the walls 421, 422, 423, and 424 may escape from the space through the first gap C1, the second gap C2, the third gap C3, and/or the fourth gap C4 during the process of placing the shielding sheet 440. Accordingly, by minimizing the amount of air with low thermal conductivity within the space surrounded by the walls 421, 422, 423, and 424, heat dissipation performance may be enhanced.

Referring to FIGS. 8 to 10, according to an embodiment of the disclosure, the distance between the first wall 421 of the walls 421, 422, 423, and 424 and the first side E21 of the second integrated circuit E2 and/or the distance between the second wall 422 of the walls 421, 422, 423, and 424 and the second side E22 of the second integrated circuit E2 may be greater than the distance between the third wall 423 of the walls 421, 422, 423, and 424 and the third side E23 of the second integrated circuit E2 and/or the distance between the fourth wall 424 of the walls 421, 422, 423, and 424 and the fourth side E24 of the second integrated circuit E2.

According to an embodiment of the disclosure, two adjacent members of the walls 421, 422, 423, and 424 (e.g., the first wall 421 and the third wall 423) may have different structures. As an example, the first wall 421 may be joined to the shield can 420 by welding, while the third wall 423 (or the fourth wall 424) may be formed by bending a portion of the shield can 420 (e.g., the edge of the cover portion 425). In another example, the second wall 422 may be joined to the shield can 420 by welding, and the third wall 423 (or the fourth wall 424) may be formed by bending a portion of the shield can 420 (e.g., the edge of the cover portion 425).

FIGS. 8 to 10 illustrate a case in which the first wall 421 and the second wall 422 of the walls 421, 422, 423, and 424 are positioned on opposite sides of the opening 426, and the third wall 423 and the fourth wall 424 of the walls 421, 422, 423, and 424 are also positioned on opposite sides of the opening 426. However, this is merely an example, and according to another embodiment, the first wall 421 or the second wall 422 may be disposed at the positions of the third wall 423 and the fourth wall 424.

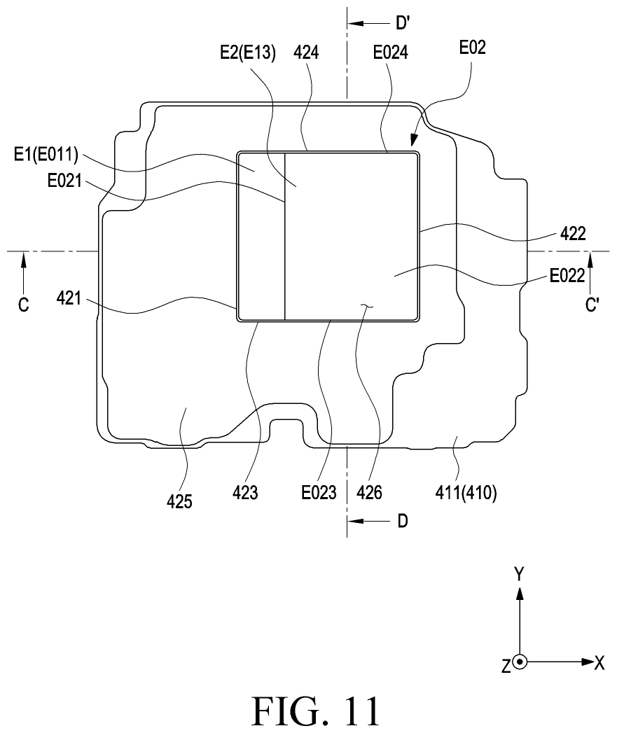

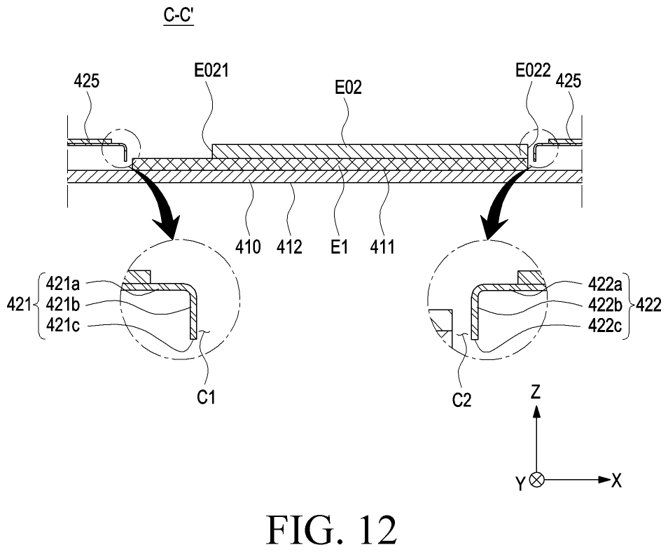

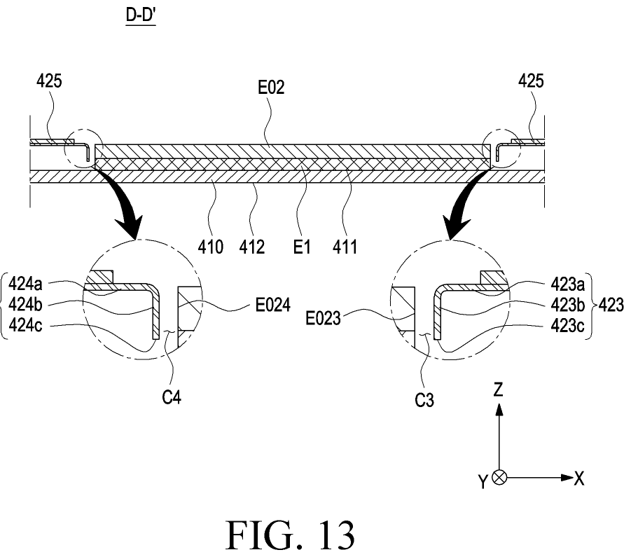

FIG. 11 is a top view of a portion of the board assembly 400 before the heat dissipation material 430 (see FIG. 5) is disposed, according to an embodiment of the disclosure. FIG. 12 is a cross-sectional view of the board assembly 400 taken along line C-C′ indicated in FIG. 11 according to an embodiment of the disclosure. FIG. 13 is a cross-sectional view of the board assembly 400 taken along line D-D′ indicated in FIG. 11 according to an embodiment of the disclosure. The embodiment illustrated in FIGS. 11 to 13 may be understood as an embodiment in which the position of the second integrated circuit E2 relative to the first integrated circuit E1 is changed compared to the embodiment illustrated in FIGS. 8 to 10.

The descriptions of the components given with reference to FIGS. 8 to 10 (e.g., the first area E13, the second areas E11 and E12, the second integrated circuit E2, the first side E21, the second side E22, the third side E23, and the fourth side E24 of the second integrated circuit E2) may be substantially equally applied to the components having the same names described with reference to FIGS. 11 to 13 (e.g., the first area E013, the second area E011, the second integrated circuit E02, the first side E021, the second side E022, the third side E023, and the fourth side E024), to the extent that they are not contradictory to each other.

Referring to FIGS. 11 to 13, according to an embodiment of the disclosure, the top surface E011/E013 of the first integrated circuit E1 may include a first area E013 and a second area E011. The second integrated circuit E02 may be disposed on the first area E013. The heat dissipation material 430 (see FIG. 5) may be disposed on the second area E011.

According to an embodiment of the disclosure, the second integrated circuit E02 may be disposed offset toward the edge of the first integrated circuit E1. The distance between the first side E021 of the second integrated circuit E02 and the first wall 421 may be greater than the distance between the second side E022 of the second integrated circuit E02 and the second wall 422. Accordingly, the second integrated circuit E02 may be disposed offset toward the second wall 422. The embodiment illustrated in FIGS. 11 to 13 in exemplary, and according to another embodiment, the distance between the first side E021 of the second integrated circuit E02 and the first wall 421 may be smaller than the distance between the second side E022 of the second integrated circuit E02 and the second wall 422. Accordingly, the second integrated circuit E02 may be disposed offset toward the first wall 421.

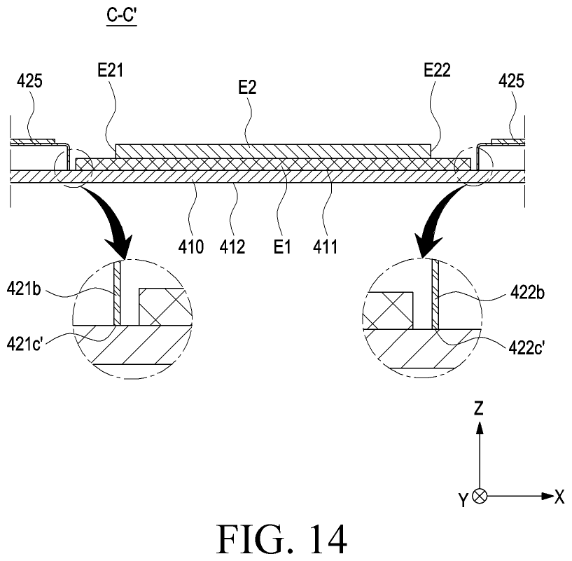

FIG. 14 is a cross-sectional view of a board assembly according to an embodiment of the disclosure, taken along line C-C′ indicated in FIG. 8. The descriptions of the end portions 421c and 422c given with reference to FIGS. 6 to 10 may be substantially equally applied to the end portions 421c′ and 422c′ described with reference to FIG. 14, to the extent that they are not contradictory to each other.

Referring to FIGS. 8 and 14, according to an embodiment of the disclosure, the ends 421c′ and 422c′ of the first wall 421 and/or the second wall 422 of the walls 421, 422, 423, and 424 may be supported by the first surface 411 of the printed circuit board 410. As an example, the end 421c′ of the first wall 421 and/or the end 422c′ of the second wall 422 may come into contact with the first surface 411 of the printed circuit board 410. As another example, the end portions 421c′ of the first wall 421 and/or 422c′ of the second wall 422 may be coupled to the first surface 411 of the printed circuit board 410 through soldering. The descriptions of the end 421c′ of the first wall 421 and/or the end 422c′ of the second wall 422 may be substantially equally applied to the end 423c of the third wall 423 and/or 424c of the fourth wall 424 (see FIG. 10).

According to another embodiment of the disclosure, by being supported by the printed circuit board 410, the ends 421c′ and 422c′ of the walls 421, 422, 423, and 424 may enhance the structural stability of the board assembly 400.

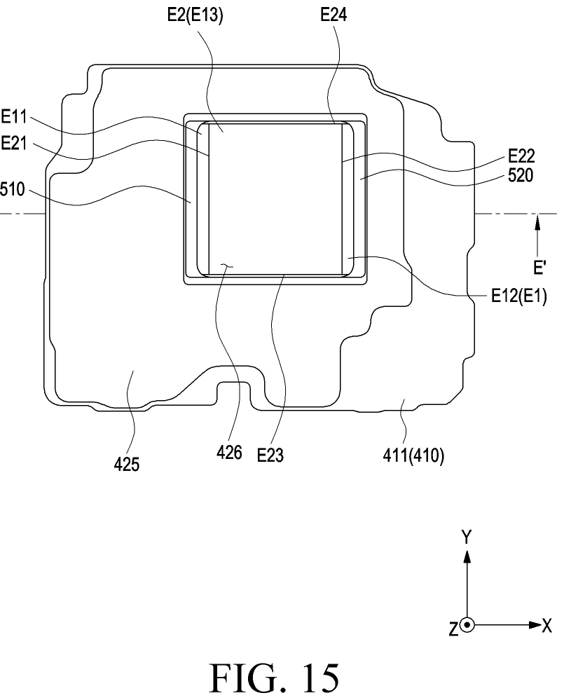

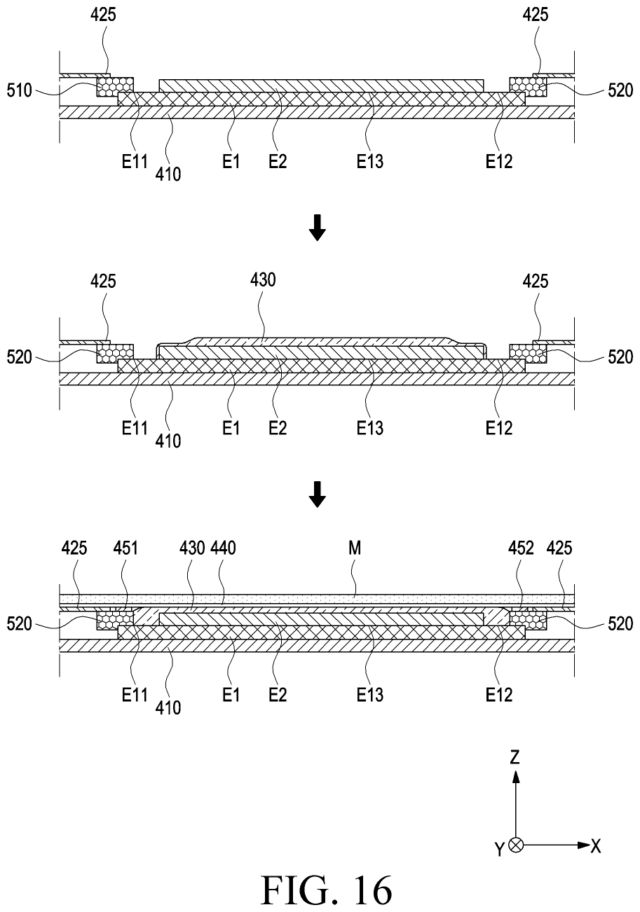

FIG. 15 is a top view of a portion of the board assembly 400 before the heat dissipation material 430 is disposed, according to an embodiment of the disclosure. FIG. 16 is a cross-sectional view of the board assembly 400 taken along line E-E′ indicated in FIG. 15, illustrating a manufacturing process of the board assembly according to an embodiment of the disclosure. The descriptions of the walls 421, 422, 423, and 424 given with reference to FIGS. 6 to 10 may be substantially equally applied to the walls 510 and 520 described with reference to FIGS. 15 and 16, to the extent that they are not contradictory to each other.

Referring to FIGS. 15 and 16, according to an embodiment of the disclosure, the board assembly 400 may include walls 510 and 520 attached to the shield can 420. The walls 510 and 520 may be attached to the edge of the cover portion 425 defining the opening 426. As an example, the walls 510 and 520 may extend in a loop shape along the edge of the opening 426. As another example, the walls 510 and 520 may include multiple members 510 and 520 extending along the edge of the opening 426, similar to the walls 421, 422, 423, and 424 described with reference to FIGS. 6 to 10.

According to an embodiment of the disclosure, the walls 510 and 520 may be supported by the edge of the first integrated circuit E1. The walls 510 and 520 may at least partially surround the heat dissipation material 430. The walls 510 and 520 may be in contact with the shielding sheet 440. By the walls 510 and 520, the heat dissipation material 430 may remain between the shielding sheet 440 and the electronic component E, more specifically, between the shielding sheet 440 and the first integrated circuit E1 and the second integrated circuit E2.

According to an embodiment of the disclosure, the walls 510 and 520 may include, for example, rubber or sponge. In another example, the walls 510 and 520 may be a heat dissipation member that is in a solid phase at room temperature (e.g., 25° C.) and includes heat dissipation particles and a paraffin-based phase change material that changes from the solid phase to a liquid phase or a gel phase at a threshold temperature (e.g., 45° C. to 65° C.). The phase change material may be a thermally responsive material that reacts to a temperature change. As an example, the phase change material may be a thermoplastic polymer. The heat dissipation particles may be carbon fiber, graphene, boron nitride (BN), silicon carbide (SIC), magnesium oxide (MgO), or zinc oxide (ZnO).

Referring to FIG. 16, the manufacturing process of the board assembly 400 according to an embodiment of the disclosure may include placing the electronic component E on the circuit board 410 and then placing the shield can 420 on the printed circuit board 410 so as to surround the electronic component E. The walls 510 and 520 attached to the shield can 420 may be supported by the edge of the first integrated circuit E1. The heat dissipation material 430 may remain in the second areas E11 and E12 of the top surface (E11, E12, and E13) of the first integrated circuit E1 due to the walls 510 and 520.

The manufacturing process of the board assembly 400 according to an embodiment of the disclosure may include applying the heat dissipation material 430 onto the electronic component E through the opening 426 of the shield can 420 and covering the opening 426 of the shield can 420 with the shielding sheet 440. As the shielding sheet 440 is placed on the shield can 420, the heat dissipation material 430 may spread into the space surrounded by the walls 510 and 520.

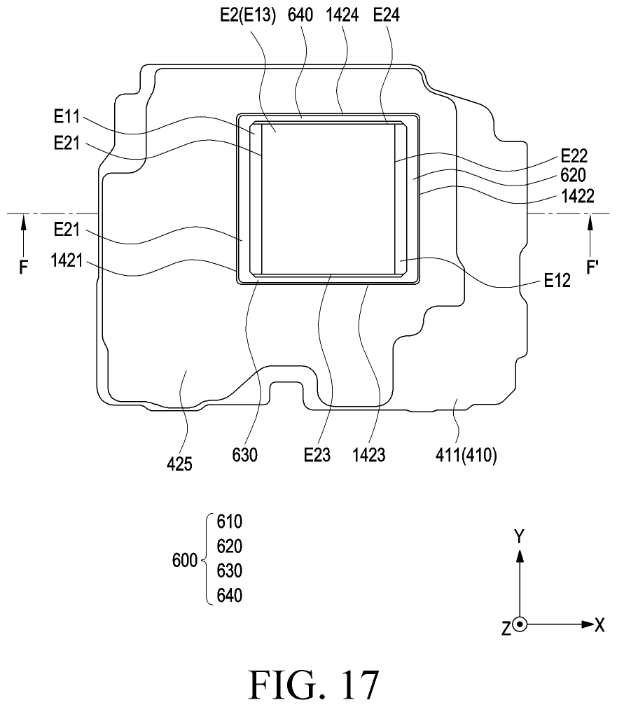

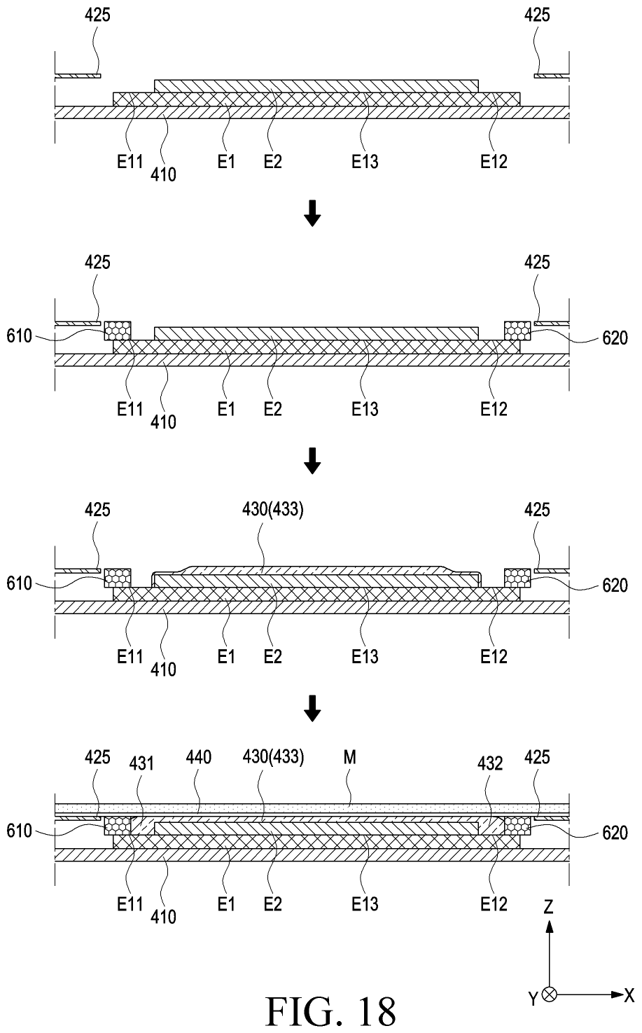

FIG. 17 is a top view of the board assembly 400 before the heat dissipation material 430 is disposed, according to an embodiment of the disclosure. FIG. 18 is a cross-sectional view of the board assembly 400 taken along line F-F′ indicated in FIG. 17, illustrating a manufacturing process of the board assembly 400. The descriptions of the walls 421, 422, 423, and 424 given with reference to FIGS. 6 to 10 may be substantially equally applied to walls 610, 620, 630, and 640 described with reference to FIGS. 17 and 18, to the extent that they are not contradictory to each other.

Referring to FIGS. 17 and 18, the board assembly 400 according to an embodiment of the disclosure may include a wall 600 disposed on the electronic component E. The wall 600 may include a first wall 610, a second wall 620, a third wall 630, and/or a fourth wall 640. For example, the wall 600 may be positioned at the edge of the first integrated circuit E1 of the electronic component E. As an example, the walls 610, 620, 630, and 640 may be made of rubber or sponge bonded to the edge of the first integrated circuit E1. As another example, the walls 610, 620, 630, and 640 may be heat dissipation members that are in a solid phase at room temperature (e.g., 25° C.) and include heat dissipation particles and a paraffin-based phase change material that changes from the solid phase to a liquid phase or a gel phase at a threshold temperature (e.g., 45° C. to 65° C.). The phase change material may be a thermally responsive material that reacts to a temperature change. As an example, the phase change material may be a thermoplastic polymer. The heat dissipation particles may be carbon fiber, graphene, boron nitride (BN), silicon carbide (SiC), magnesium oxide (MgO), or zinc oxide (ZnO).

According to an embodiment of the disclosure, the walls 610, 620, 630, and 640 may be in contact with the edge of the cover portion 425 defining the opening 426. The walls 610, 620, 630, and 640 may extend in a loop shape along the edge of the opening 426. As another example, the walls 610, 620, 630, and 640 may include multiple members 610, 620, 630, and 640 extending along the edge of the opening 426, similar to the walls 421, 422, 423, and 424 described with reference to FIGS. 6 to 10.

According to an embodiment of the disclosure, the walls 610, 620, 630, and 640 may at least partially surround the heat dissipation material 430. The walls 610, 620, 630, and 640 may be in contact with the shielding sheet 440. By the walls 610, 620, 630, and 640, the heat dissipation material 430 may remain between the shielding sheet 440 and the electronic component E, more specifically, between the shielding sheet 440 and the first integrated circuit E1 and the second integrated circuit E2.

Referring to FIG. 18, the manufacturing process of the board assembly 400 according to an embodiment of the disclosure may include placing the electronic component E on the circuit board 410 and then placing the shield can 420 on the printed circuit board 410 so as to surround the electronic component E.

The manufacturing process of the board assembly 400 according to an embodiment of the disclosure may include placing the walls 610, 620, 630, and 640 at the edge of the electronic component E. The walls 610, 620, 630, and 640 may be fixed to the edge of the first integrated circuit E1. As an example, the walls 610, 620, 630, and 640 may be bonded to the edge of the first integrated circuit E1 via an adhesive member (e.g., double-sided tape).

The manufacturing process of the board assembly 400 according to an embodiment of the disclosure may include applying the heat dissipation material 430 onto the electronic component E through the opening 426 of the shield can 420 and covering the opening 426 of the shield can 420 with the shielding sheet 440. As the shielding sheet 440 is placed on the shield can 420, the heat dissipation material 430 may spread into the space surrounded by the walls 610, 620, 630, and 640. According to an embodiment of the disclosure, the wall 600 may be attached to the edge of the first integrated circuit E1 and may be in contact with the shielding sheet 440.

As the integration density and performance of electronic components (e.g., processors and memory) increase, the amount of heat generated by electronic components is also increasing. If the temperature of the electronic component due to heat generation is not reduced, it may affect the operation of the electronic device (e.g., performance degradation due to throttling). Thus, extensive research is being conducted on the heat dissipation structures of electronic components.

An issue to be addressed by the disclosure may be to minimize the flow of a flowable heat dissipation material inside an electronic device.

An issue to be addressed by the disclosure may be to improve heat dissipation performance through a flowable heat dissipation material.

The problems that the disclosure seeks to solve are not limited to the aforementioned problems, and may be expanded in various ways without departing from the spirit and scope of the disclosure.

An electronic device according to various embodiments of the disclosure may minimize the flow of a heat dissipation material inside the electronic device by restricting the flow of the heat dissipation material by placing of walls surrounding the space in which the heat dissipation material is disposed.

An electronic device according to various embodiments of the disclosure may improve the heat dissipation performance of an electronic component by restricting the flow of a heat dissipation material by placing walls surrounding the space in which the heat dissipation material is disposed.

The effects that are capable of being obtained by the disclosure are not limited to those described above, and other effects not described above may be clearly understood by a person ordinarily skilled in the art to which the disclosure belongs based on the following description.

According to an embodiment of the disclosure, an electronic device 101 may include a housing 301, and a board assembly 400 disposed inside the housing 301.

According to an embodiment of the disclosure, the board assembly may include a printed circuit board 410 including a first surface 411 and a second surface 412 opposite to the first surface 411.

According to an embodiment of the disclosure, the board assembly 400 may include an electronic component E disposed on the first surface 411.

According to an embodiment of the disclosure, the board assembly 400 may include a shielding member S disposed on the first surface 411 and surrounding the electronic component E.

According to an embodiment of the disclosure, the shielding member S may include a shield can 420 including an opening 426 overlapping the electronic component E when viewed from above the first surface 411, and a shielding sheet 440 covering the opening 426.

According to an embodiment of the disclosure, the board assembly 400 may include a heat dissipation material 430 disposed between the electronic component E and the shielding sheet 440.

According to an embodiment of the disclosure, the board assembly 400 may include a wall 421, 422, 423, or 424 disposed inside the shielding member S and extending along an edge of the electronic component E to at least partially surround the heat dissipation material 430.

According to an embodiment of the disclosure, the shield can 420 may include a cover portion 425 covering the electronic component E, defining the opening 426, and forming an integral structure with the wall 421, 422, 423, or 424.

According to an embodiment of the disclosure, the wall 421 or 422 may include a first portion 421a or 422a connected to the cover portion 425.

According to an embodiment of the disclosure, the wall 421 or 422 may include a second portion 421b or 422b bent from the first portion 421a or 422a toward the first surface 411 of the printed circuit board 410.

According to an embodiment of the disclosure, the second portion 421b or 422b of the wall 421 or 422 may be supported by the first surface 411 of the printed circuit board 410.

According to an embodiment of the disclosure, the electronic component E may include a first integrated circuit E1 disposed on the first surface 411 of the printed circuit board 410.

According to an embodiment of the disclosure, the electronic component E may include a second integrated circuit E2 stacked on the first integrated circuit E1 and operatively connected to the first integrated circuit E1.

According to an embodiment of the disclosure, the wall 421, 422, 423, or 424 may extend along a side E21, E22, E23, or E24 of the second integrated circuit E2.

According to an embodiment of the disclosure, the wall 421, 422, 423, or 424 may be spaced apart from the side E21, E22, E23, or E24 of the second integrated circuit E2 and may face the side E21 or E22 of the second integrated circuit E2.

According to an embodiment of the disclosure, the wall 421, 422, 423, or 424 may be bent from the shield can 420 toward the first surface 411 of the printed circuit board 410, and an end of the wall 421c, 422c, 423c, or 424c may be spaced apart from the edge of the electronic component E.

According to an embodiment of the disclosure, the wall 421, 422, 423, or 424 may include a first wall 421 or 422 extending along a first side E21 or E22 of the second integrated circuit E2.

According to an embodiment of the disclosure, the wall 421, 422, 423, or 424 may include a second wall 423 or 424 extending along a second side E23 or E24 of the second integrated circuit E2 which intersects with the first side E21 or E22.

According to an embodiment of the disclosure, the distance between the first wall 421 or 422 and the first side E21 or E22 is greater than the distance between the second wall 423 or 424 and the second side E23 or E24.

According to an embodiment of the disclosure, one of the first wall 421 or 422 and the second wall 423 or 424 is coupled to the shield can 420 and the other may be formed by bending a portion of the shield can 420.

According to an embodiment of the disclosure, the wall 510 or 520 may be bonded to the edge 425 of the shield can 420 which defines the opening 426, and the wall 510 or 520 may be in contact with the shielding sheet 440.

According to an embodiment of the disclosure, the walls 510 and 520 may be supported by the edge of the first integrated circuit E1.

According to an embodiment of the disclosure, the wall 600 may be attached to the edge of the first integrated circuit E1 and may be in contact with the shielding sheet 440.

According to an embodiment of the disclosure, the top surface E11, E12, and E13 of the first integrated circuit E1 may include a first area E13 on which the second integrated circuit E2 is disposed.

According to an embodiment of the disclosure, the top surface E11, E12, and E13 of the first integrated circuit E1 may include a second area E11 or E12, in which a portion 431 or 432 of the heat dissipation material 430 is disposed.

According to an embodiment of the disclosure, the portion 431 or 432 of the heat dissipation material 430 may be positioned between the second integrated circuit E2 and the wall 421 or 422.

According to an embodiment of the disclosure, the heat dissipation material 430 may be configured to have at least partially a liquid phase or a gel phase.

According to an embodiment of the disclosure, the walls 510 and 520 or 600 may include a phase change material configured to be in a solid phase at room temperature and to change from the solid phase to a liquid phase or a gel phase at a threshold temperature.

The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. An electronic device comprising:
a housing; and
a board assembly disposed inside the housing,
wherein the board assembly comprises:
a printed circuit board comprising a first surface, and a second surface opposite to the first surface;
an electronic component disposed on the first surface;
a shielding member disposed on the first surface and surrounding the electronic component, wherein the shielding member comprises:
a shield can comprising an opening that is overlapping the electronic component when viewed from above the first surface, and
a shielding sheet covering the opening;
a heat dissipation material disposed between the electronic component and the shielding sheet; and
a wall disposed inside the shielding member and extending along an edge of the electronic component, the wall at least partially surrounding the heat dissipation material.

2. The electronic device of claim 1, wherein the shield can comprises a cover portion that is integral with the wall and is defining the opening.

3. The electronic device of claim 2, wherein the wall comprises:
a first portion connected to the cover portion; and
a second portion extending from the first portion toward the first surface of the printed circuit board.

4. The electronic device of claim 3, wherein the second portion of the wall is disposed on the first surface of the printed circuit board.

5. The electronic device of claim 1, wherein the electronic component comprises:
a first integrated circuit disposed on the first surface of the printed circuit board; and
a second integrated circuit stacked on the first integrated circuit and operatively connected to the first integrated circuit, and
wherein the wall extends along a side of the second integrated circuit.

6. The electronic device of claim 5, wherein the wall is spaced apart from the side of the second integrated circuit and is facing the side of the second integrated circuit.

7. The electronic device of claim 5, wherein the wall is extends from the shield can toward the first surface of the printed circuit board, and
wherein an end of the wall is spaced apart from the edge of the electronic component.

8. The electronic device of claim 5, wherein the wall comprises:
a first wall extending along a first side of the second integrated circuit; and
a second wall extending along a second side of the second integrated circuit, the second side intersecting the first side, and
wherein a distance between the first wall and the first side is greater than a distance between the second wall and the second side.

9. The electronic device of claim 8, wherein one of the first wall or the second wall is coupled to the shield can and a another of the first wall or the second wall is bent from a portion of the shield can.

10. The electronic device of claim 5, wherein the wall is bonded to an edge of the shield can, the edge defining the opening, and the wall being in contact with the shielding sheet.

11. The electronic device of claim 10, wherein the wall is disposed on an edge of the first integrated circuit.

12. The electronic device of claim 5, wherein the wall is bonded to an edge of the first integrated circuit and is in contact with the shielding sheet.

13. The electronic device of claim 5, wherein the first integrated circuit comprises, on a top surface thereof:
a first area on which the second integrated circuit is provided; and
a second area on which a portion of the heat dissipation material is provided, and
wherein the second area is between the second integrated circuit and the wall.

14. The electronic device of claim 1, wherein the heat dissipation material comprises a material that is configured to be at least partially in a liquid phase or in a gel phase.

15. The electronic device of claim 14, wherein the wall comprises a phase change material that is configured to be in a solid phase at room temperature, and configured to be in the liquid phase or the gel phase at a threshold temperature.

16. A board assembly, comprising:
a printed circuit board comprising a first surface, and a second surface opposite to the first surface;
an electronic component disposed on the first surface;
a shielding member disposed on the first surface and surrounding the electronic component, wherein the shielding member comprises:
a shield can comprising an opening that is overlapping the electronic component when viewed from above the first surface, and
a shielding sheet covering the opening;
a heat dissipation material between the electronic component and the shielding sheet; and
a wall inside the shielding member and extending along an edge of the opening, the wall at least partially surrounding the heat dissipation material.

17. The board assembly of claim 16, wherein the electronic component comprises:
a first integrated circuit disposed on the first surface of the printed circuit board; and
a second integrated circuit stacked on the first integrated circuit and operatively connected to the first integrated circuit, and
wherein the wall extends along a side of the second integrated circuit.

18. The board assembly of claim 17, wherein the wall comprises:
a first wall extending along a first side of the second integrated circuit; and
a second wall extending along a second side of the second integrated circuit, the second side intersecting the first side, and
wherein a distance between the first wall and the first side is greater than a distance between the second wall and the second side.

19. The board assembly of claim 16, wherein the shield can comprises a cover portion that is integral with the wall and is defining the opening.

20. The board assembly of claim 16, wherein the heat dissipation material comprises a material that is configured to be at least partially in a liquid phase or a gel phase.
